(19) United States
(12) Patent Application Publication
(10) Pub. No.: US 2003/0093737 A1
(43) Pub. Date: May 15, 2003

(54) Event based test system having improved semiconductor characterization map

(76) Inventors: Michael Purtell, Santa Clara, CA (US); Hiroaki Yamoto, Santa Clara, CA (US)

Correspondence Address: MURAMATSU & ASSOCIATES, Suite 225, 7700 Irvine Center Drive, Irvine, CA, 92618, US

(21) Appl. No.: 10/008,408

(22) Filed: Nov. 13, 2001

(51) Int. Cl. G01R 31/28

(52) U.S. Cl. 714/738

(57) ABSTRACT

An event based test system having an improved characterization tool for semiconductor device testing. The characterization map provides multi-dimensional views of device performance for debug of the design, and identification of performance weaknesses. The characterization map tool exploits the capabilities of the event based test system. The multi-dimensional views include a checkerboard map such as displaying pins versus time, a shmoo plot showing pass-fail boundary points relative to predetermined parameters, or a margin map showing a pass/fail range for pins corresponding with timing changes in one or more events.

### FIELD OF THE INVENTION

This invention relates to an event based test system having an improved characterization tool for semiconductor device testing, and more particularly, to a characterization tool for use with a semiconductor test system to display various test parameters including test patterns, device response and test result analysis in a two or three dimensional manner.

### BACKGROUND OF THE INVENTION

In testing semiconductor devices such as ICs and LSIs by a semiconductor test system, such as an IC tester, a semiconductor IC device to be tested is provided with test patterns produced by a semiconductor test system at its appropriate pins at predetermined test timings. The semiconductor test system receives output signals from the IC device under test in response to the test signals. The output signals are strobed or sampled at predetermined timings to be compared with expected data to determine whether the IC device functions correctly.

The semiconductor test system displays the test results or device characteristics through a host computer using a GUI (graphic user interface). Such test processes and device characterization are applied to a large population of devices under test to determines the operating performance, design and process statistics. This step relies heavily on characterization tools. The device characterization is used for determination of performance margins, which expose design weaknesses. This information can be used to improve the design process or production process, leading to yield improvement, reduced manufacturing cost, and improved quality.

Traditionally, timings of the test signals and strobe signals are defined relative to a tester rate or a tester cycle of the semiconductor test system. Such a test system is sometimes called a cycle based test system or a cyclized test system. In such a conventional semiconductor test system, there are several known characterization tools that are used to predict a smaller number of device parameters, and most of these only operate in a two dimensional mode.

Examples of these tools include a logic analyzer display tool which shows the input and output waveforms of the device, with overlay of cyclization references (cycle boundary and time set), and the compare timing. This tool is useful in a cycle-based environment such as in the traditional cycle based test system. In the design environment such as EDA (electronic design automation), a tool called “Signal Scan” which is similar to the logic analyzer tool is used to view the signal waveform.

Another tool is a shmoo plot which has been used for many years to characterize the relationship between two parameters or conditions, and to show their effects on the device pass/fail characteristics. A typical use is with power supply voltage as one parameter (y-axis), and cycle length (x-axis) as a second parameter. Viewing this kind of shmoo plot provides powerful insight into the effect of power supply voltage on maximum frequency of operation, commonly called Fmax. Cycle based test systems move the edge in every time set used by the test pattern, making it difficult to isolate the specific cycle that was slowest, or defective.

A further example is a system viewer tool provided to the semiconductor test system. The system viewer tool on cycle based test systems allows the user to inspect and modify test conditions at a specific point of program execution. The inspection identifies programming errors, and the modification of the test conditions allows the user to quickly check to see if their solution is effective without modifying test program code.

The assignee of this invention has proposed a new type of test system which is an event based test system wherein the desired test signals and strobe signals are produced by event data from an event memory directly on a per pin basis. In the event based test system, the event timing and event repetition rate can be freely modified by an event offset function and an event scaling function. The conventional characterization tools noted above are insufficient to fully utilized the capability of the event test system. Thus, there is a need of new characterization tools in the event based test system to fully illustrate the device characteristics utilizing the new functions of the event based test system.

### SUMMARY OF THE INVENTION

It is, therefore, an object of the present invention to provide a semiconductor characterization map which is capable of displaying various test parameters including test patterns, device response and test result analysis in a two or three dimensional manner.

It is another object of the present invention to provide a semiconductor characterization map wherein various test parameters can be easily modified and displayed in a two or three dimensional manner.

It is a further object of the present invention to provide a semiconductor test system having a three dimensional characterization map for displaying and modifying various test parameters.

In the event based test system, for producing a test pattern by using the event based method, it is only necessary to read set/reset data and associated timing data stored in an event memory, requiring very simple hardware and software structures. Further, each test pin can operate independently as to whether there is any event therein rather than the test cycle and various types of associated data, thus, test patterns of different functions and frequency ranges can be generated at the same time. Therefore, it is possible to establish a characterization map which provides sufficient information and is flexible enough to modify various test parameters.

The characterization map of the present invention provides three-dimensional views of device performance for debug of the design, and identification of performance weaknesses. The characterization map tool exploits the capabilities of the event based test system. The three dimensional views include a checkerboard map such as displaying pins versus time, a shmoo plot showing pass-fail boundary points relative to predetermined parameters, or a margin map showing a pass/fail range for pins corresponding with timing changes in one or more events.

### BRIEF DESCRIPTION OF THE DRAWINGS

FIG. 1 is a block diagram showing functions of the event based semiconductor test system supporting the characterization map display of the present invention and an overall relationship between the test system and an EDA (electronic design automation) environment.

FIG. 2 is a schematic diagram showing an example of semiconductor characterization map of the present invention which displays the test parameters and test results in a three dimensional fashion.

FIGS. 3A and 3B are schematic diagrams showing examples of semiconductor characterization map of the present invention which display the test results in a checker board format where a time scale in FIG. 3B is compressed to cover a wider time range.

FIGS. 4A-4C are schematic diagrams showing examples of semiconductor characterization map of the present invention where FIG. 4A is a shmoo plot of a single device, FIG. 4B is a composite map of shmoo plots of multiple devices, and FIG. 4C is an enlarged view of FIG. 4B or 4C.

FIGS. 5A and 5B are schematic diagrams showing examples of semiconductor characterization map of the present invention where FIG. 5A is a margin map showing a timing relationship between a device output and strobe signals and FIG. 5B is a timing diagram showing the waveforms defined in FIG. 5.

### DETAILED DESCRIPTION OF THE INVENTION

In the previous applications owned by the same assignee of this invention, an event based test system is described in U.S. patent application Ser. Nos. 09/406,300 and 09/340,371 “Event based semiconductor test system”. Further, a time scaling technology is described in U.S. patent application Ser. No. 09/286,226 “Scaling logic for Event Based Test System”. All of these patent applications are incorporated by reference.

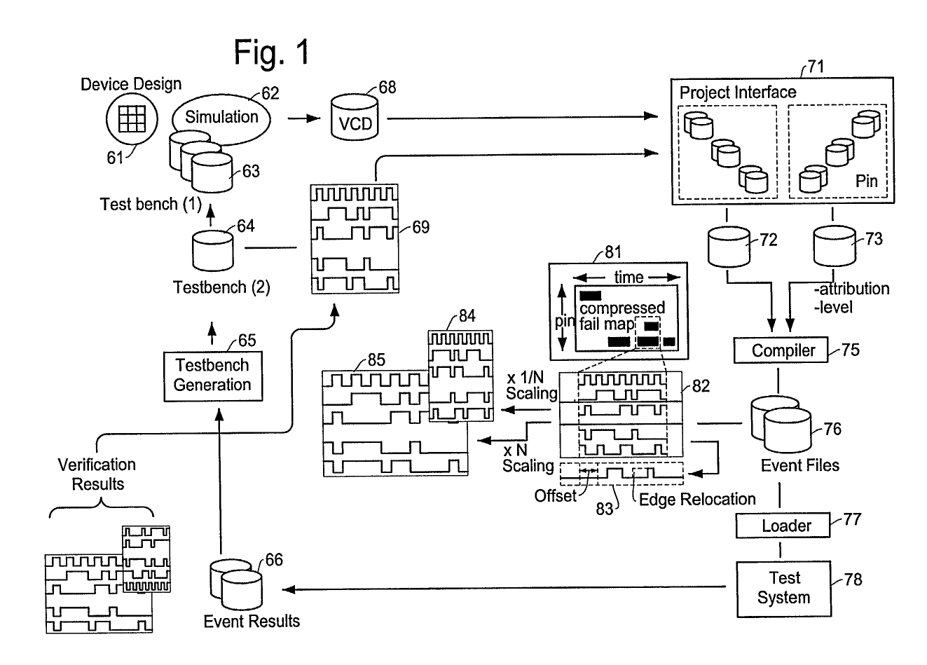

FIG. 1 is a flow diagram showing functions and display examples of the event based test system for achieving the characterization map display of the present invention. The example of FIG. 1 also shows a relationship between the event based test system and an EDA (electronic design automation) environment. With use of the semiconductor characterization map of the present invention, the test results obtained by the event test system can effectively be feedbacked to the EDA environment, thereby improving the design in a short period of time.

In FIG. 1, by executing a logic simulation process 62 on the LSI design data 61 with use of a testbench 63 (available in the market) or a testbench 64 (specifically created for a tester), a value change dump (VCD) file 68 is produced. Through an interface 71, files 72 and 73 are created by assigning the event data from the dump file 68 or event data 69 from the testbench 64 to each test pin and defining signal level of each event. The data from the files 72 and 73 is converted to object codes by a compiler 75, thereby forming an event file 76.

When conducting a test on the device, the event data is transferred from the file 76 to an event test system 78 by a loader 77. Based on the event data stored in an event memory, the event test system 78 generates an event based test pattern, thereby executing the test on the device under test. The test result is accumulated in a test result file 66 to be used in, for example, failure analysis. The test result accumulated in this manner can be feedbacked to the testbench through a testbench generator 65.

As described in the prior applications, the event data formed in the event file directly describes the test pattern to be applied to the device under test. Therefore, with use of the event data, through graphic user interface (GUI), the pattern sequence identical to the actual test pattern can be displayed. Such a pattern sequence can be easily modified through the graphic display. Thus, device characterization maps of various parameters are available in the present invention. An example such characterization maps is shown in FIG. 1 by screens 81-85.

For example, the screen 81 shows an overall image of a pass/fail map (checkerboard map) having tester pins (device pins) in a vertical axis and time interval (test pattern) in a horizontal axis. The screen 82 provides an enlarged view 82 of a portion of the test pattern specified in the fail map shown in the screen 81. The screen 83 shows an example of changing the timing (timing offset) of a specific event, i.e, edge relocation.

The screens 84 and 85 show the scaling function in which the timings are decreased (84) or increased (85) by a predetermined factor, Such changes in the parameters on the display can be done by modifying the data in the event file, which also changes the actual test pattern applied to the device under test and thus enables to monitor the resultant response of the device under test. The more details regarding the scaling of the timing data is given in U.S. patent application Ser. No. 09/286,226 and U.S. Pat. No. 6,226,765 owned by the same assignee of this invention.

As noted above, the event based test system includes the fail compress time domain display (checkerboard map) such as shown in the screen 81. This function is a two dimensional display of squares aligned as rows and columns. The rows represent pins or pin groups and are labeled accordingly on the left side of the display. The columns represent time intervals, with earlier times shown on the left. A horizontal scroll bar (not shown) allows the view to be positioned anywhere between the beginning and end of the pattern. If any failures occur within the time interval and pins represented by the box, it is colored, for example, red. If no failures occur, the box is colored, for example, green. The time scaling is used to expand or compress the time interval (scaling function), and can be used to find out if a colored box indicates multiple failures, or just a single failure.

Another function of the event based test system is the timing offset such as shown in the screen 83. The timing of the event (drive event, compare event) is changed by pin and pin group. This function enables all timing edges to be shifted by the same amount for the entire run time of a pattern. A few examples, which employ this capability, are generation of characterization data to find either the slowest response in a series of device outputs, or the longest set up time in a series of input writes to a memory or programmable logic device. This function also enables a timing edge of only a specific event be shifted by a specified amount or even be deleted from the test pattern.

The event scaling noted above is unique to the event based test system. This feature compresses or expands an entire set of drive and compare events. It is a very simple way to relax or tighten the timing applied to testing the device, to see where the pass/fail threshold occurs. This is one of the quickest ways to quantify the speed of the device. The scaling cannot be universally applied to a conventional tester, i.e., cycle based test system.

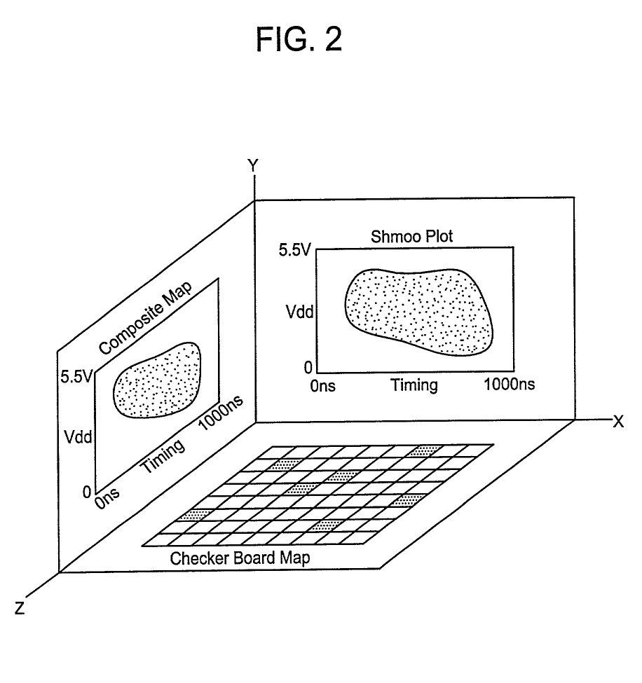

FIG. 2 shows an example of semiconductor device characterization map of the present invention. In this example, the test results are displayed in a three dimensional fashion (XYZ axes) which includes a checkerboard map, a shmoo plot, and a composite map where many other combinations are possible. The characterization map of FIG. 2 provides three dimensional views of device performance for debug of the design, and identification of performance weaknesses. The characterization map tool exploits the capabilities on the event based test system such as the timing scaling, timing offset, failure compress, and the like as noted above with reference to FIG. 1.

The checkerboard map displays the test results configured, for example, by pins versus time. This example indicates pass/fail of pins of the device under test with respect to a time length of a test pattern. The shmoo plot shows pass-fail boundary points relative to predetermined parameters. Typically, such parameters are supply voltage of the device under test and the input clock signal frequency to the device under test. The margin map shows a pass/fail range for pins corresponding with timing changes in one or more events such as compare (strobe) events and drive events.

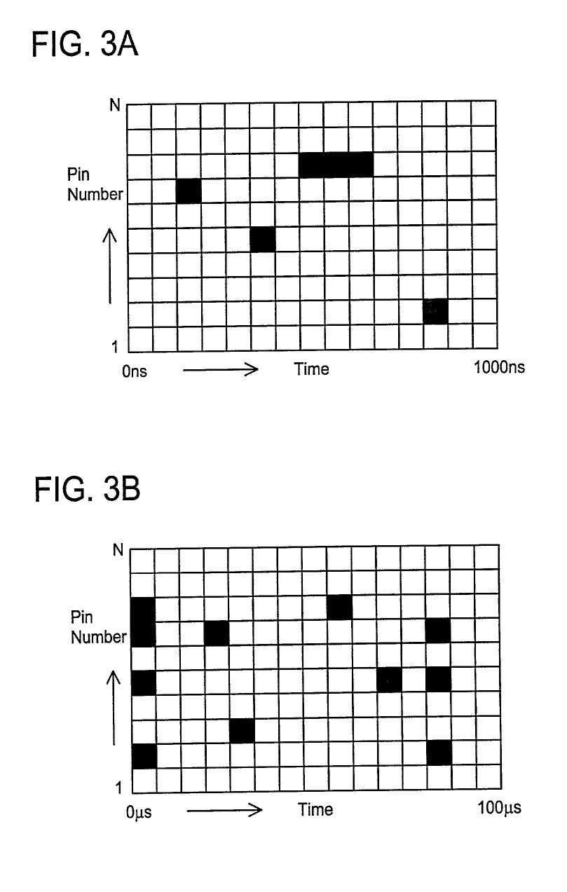

Simultaneous display of all three planes provides a unique insight into the behavior of a single device or a population of devices. If the users are only interested in one of the three planes, they can easily display only the plane that they are interested in, as in FIGS. 3-5. The setup of each plane can be done in either the two dimensional or in the three dimensional view.

Further examples of checkerboard map are shown in FIGS. 3A and 3B (fail compress time domain display). The time scale in FIG. 3B is compressed to cover a time range wider than that of FIG. 3A. This plane displays pins or pin groups on one axis, and time length or time intervals on the other. Results of compare events, which are affected by input stimulus, power, and previous device states (sequential circuits) are displayed. Regions having one or more failures on the corresponding pin or pin group and the time interval represented by the box may be colored, for example, in red. Regions, which may be colored in green, have no failures on the pin or pin group and the time interval represented by the box.

This view can be expanded or compressed to adjust resolution with use of the timing scaling function of the event based test system. Thus, FIG. 3A shows the time range of 0-1,000 ns (nanosecond) while FIG. 3B shows the time range of 0-100 μs (microsecond). Accordingly, the time compressed view of FIG. 3B covers the wider time range while the fail indication shows one or more fails in an enlarged time interval.

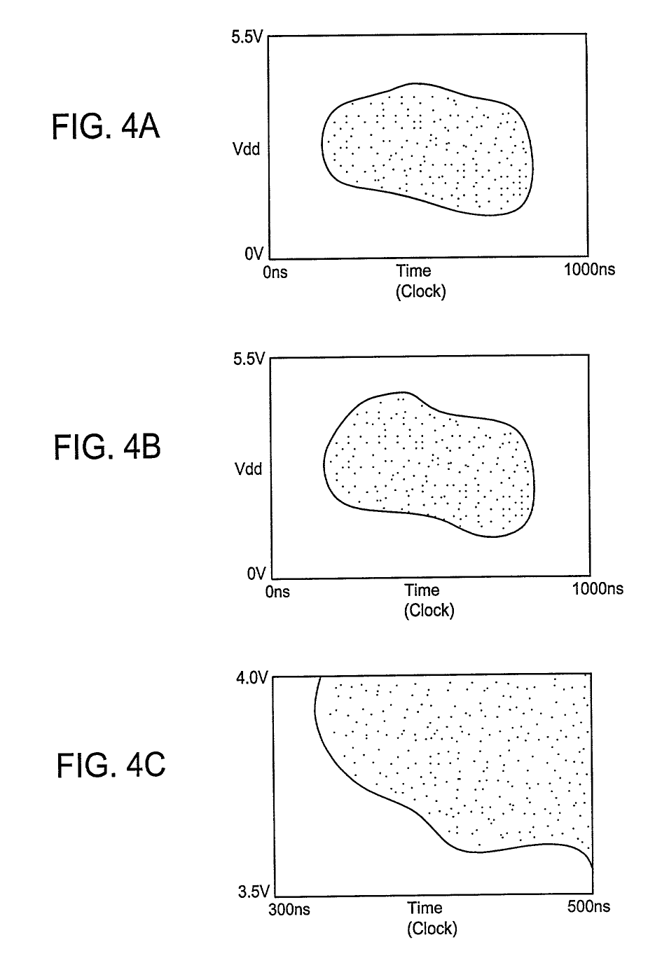

FIGS. 4A-4C show other examples of characterization map of the present invention. FIG. 4A is a shmoo plot of a single device and FIG. 4B is a composite display of shmoo plots of multiple devices, and FIG. 4C is an enlarged view of FIG. 4B or 4C. A shmoo plot is a graphical representation of an ability of a device under test to operate properly in response to various combinations of values of two operating parameters. For example, one parameter (vertical axis) is a supply voltage to the device under test and the other parameter (horizontal axis) is a clock frequency input to the device under test.

The composite map of FIG. 4B is used to display the effect of several devices or several timing parameter variations on pass/fail result and pass/fail threshold points. This tool allows viewing a population of devices according to failure mode, or location of first failure in the event file. For example, an averaged pass/fail of a plurality of devices is illustrated relative to an input clock frequency (time interval).

The vertical axis of FIGS. 4A and 4B is a supply voltage with the range of 0-5V (volt) and the horizontal axis thereof is a clock frequency with the range of 0-1,000 ns (nanosecond). The vertical axis of the enlarge view of FIG. 4C is a supply voltage with the range of 3.5-4V (volt) and the horizontal axis thereof is a clock frequency with the range of 300-500 ns (nanosecond). Thus, the view of FIG. 4C provides an enlarged view of a portion of the view in FIGS. 4A and 4B. The horizontal axis can also be used to represent a time-scale factor, rather than the absolute time, which is used to proportionately relax or stress the timing.

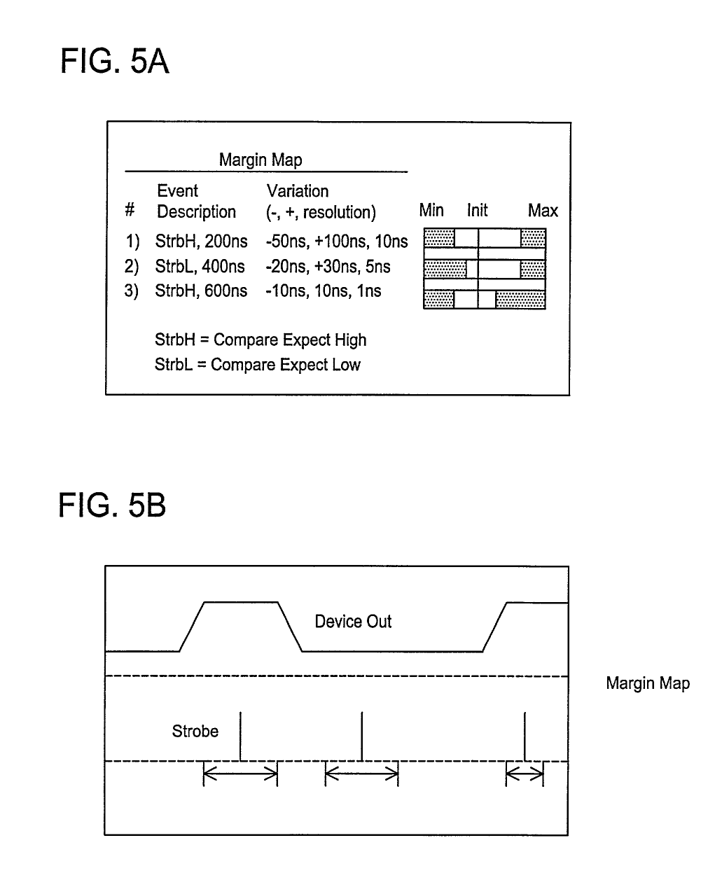

FIGS. 5A and 5B show another example of semiconductor characterization map of the present invention. FIG. 5A is a margin map showing a timing relationship between a device output and compare events (strobe signals) and FIG. 6B is a timing diagram showing the waveforms of FIG. 5. The margin map can be used to find the pass/fail range for individual pins or pin groups corresponding with one or more events. The margin map tool applies the timing offset function of a pin or pin group to find the pass/fail of interest. The current programmed value is noted on the display, allowing the user to see how close the device is to the pass/fail threshold.

As described in the foregoing, the three dimensional view of the checkerboard map, the shmoo plot from a single device, and the composite shmoo from a plurality of devices provides much more information about device behavior than the previously used methods. For example, to determine whether the behavior of one device is typical or aberrant, the shmoo and composite characterization map provides sufficient information to the question. When it is desired to know which pins are failing and at what times, the checkerboard map provides the direct and sufficient data to that question.

Further, to determine the relationship between the pass fail behavior and other parameters, the shmoo and composite characterization map show proper information to that question. In the case to evaluate how sensitive the events that are passing, the margin map provides direct information to that question. The characterization map of the present invention provides sufficient and useful information to fully evaluate the device design and the resultant semiconductor devices.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. An event based semiconductor test system for testing semiconductor devices and displaying test parameters and test results, comprising:
means for generating a test pattern and applying the test pattern to a semiconductor device under test;
means for evaluating a response output of the semiconductor device under test and collecting test result data; and
a host computer for controlling an overall operation of the event based test system and for displaying test parameters and the test result data;
wherein the host computer displays a device characterization map in which the test parameters and the test result data are illustrated in a multi-dimensional manner on X, Y and Z axes.

2. An event based semiconductor test system as defined in claim 1, wherein the characterization map includes a checkerboard map which shows the test results configured by pins versus time, a shmoo plot which shows pass-fail boundary points relative to predetermined parameters with respect to a single device under test, a composite map which shows a composite data of shmoo plots of a plurality of devices under test, a margin map which shows pass/fail ranges for individual pins or pin groups corresponding with one or more events, and a waveform display which shows a test pattern to be applied to the device under test based on the event data from the event memory.

3. An event based semiconductor test system as defined in claim 1, wherein the characterization map includes a checkerboard map which shows the test results configured by pins versus time wherein a time scale of the checkerboard map is expanded or compressed by a timing scaling function of the event based test system.

4. An event based semiconductor test system as defined in claim 1, wherein the characterization map includes a shmoo plot which shows pass-fail boundary points relative to predetermined parameters with respect to a single device under test and a composite map which shows a composite data of shmoo plots of a plurality of devices under test wherein a time scale of the shmoo plot or composite map is expanded or compressed by a timing scaling function of the event based test system.

5. An event based semiconductor test system as defined in claim 1, wherein the characterization map includes a margin map which shows pass/fail ranges for individual pins or pin groups corresponding with one or more events wherein a position of an edge of the event is changed by a timing offset function of the event based test system.

6. An event based semiconductor test system as defined in claim 1, wherein the characterization map displays the waveforms of the test pattern to be applied to the device under test based on the event data from the event memory, wherein the characterization map shows an overall illustration of the test pattern, an enlarged view of a part of the test pattern, timing changes in each event in the test pattern, and/or offset addition or removal from the test pattern.
